(19) United States
(12) Patent Application Publication
(10) Pub. No.: US 2010/0002400 A1
(43) Pub. Date: Jan. 7, 2010

(54) DAUGHTER BOARD WITH SOLID-STATE STORAGE DEVICE FOR USE IN COMPUTER SYSTEM

(75) Inventor: Jui-Hua Lin, Taipei (TW)

Correspondence Address: WPAT, PC;INTELLECTUAL PROPERTY ATTORNEYS, 7225 BEVERLY ST., ANNANDALE, VA, 22003, US

(73) Assignee: ASUSTeK COMPUTER INC., Taipei (TW)

(21) Appl. No.: 12/476,742

(22) Filed: Jun. 2, 2009

(30) Foreign Application Priority Data
Jul. 1, 2008 (TW) 097124795

(51) Int. Cl. H05K 7/02; H05K 1/02

(52) U.S. Cl. 361/736; 361/737

(57) ABSTRACT

A daughter board of a computer system is connected to a front panel of a computer housing. The daughter board includes a main body mounted thereon a solid-state storage device for storing data and a control circuit for control data access to the solid state storage device, for example, by surface mount technology.

### FIELD OF THE INVENTION

The present invent relates to a daughter board of a computer system, and more particularly to a daughter board with a solid-state storage device for use in a computer system.

### BACKGROUND OF THE INVENTION

As known to those ordinary in the art, there is usually a front I/O printed circuit board or a front I/O daughter board (hereinafter, “daughter board”) mounted onto a front panel of a computer housing. Please refer to FIG. 1A and FIG. 1B, which illustrate relative positions of the daughter board to the computer housing. Generally, there are several transmission ports 10, 11 and 12 and at least one light-emitting-diode (LED) indicator light 13 for informing a user of the operations of the computer, e.g. a power indicator light indicating the state of the computer host and/or a hard-disk indicator light indicating the state of a hard disk drive, arranged on a front panel 15. The transmission ports 10, 11 and 12 and the LED indicator light 13 are typically provided onto the front panel 15 via a daughter board 14 where circuitry associated with the transmission ports 10, 11 and 12 and the LED indicator light 13 are mounted by surface mount technology (SMT) or dual in-line package (DIP). FIG. 1B illustrates an example for disposing the daughter board, in which the daughter board 14 is physically connected to the front panel 15 with a surface thereof. Conventionally, the transmission ports mounted on the daughter board 14 only include a headphone or earphone port 10 for audio input, a microphone port 11 for audio output and a universal serial bus (UBS) port 12 for USB signal transmission, wherein the USB port 12 is further in communication with a main board (not shown) via a USB cable, and the other transmission ports and indicator light are in communication with the main board via respective signal lines. In other words, the daughter board only exhibit data transmission functions.

### SUMMARY OF THE INVENTION

Therefore, an object of the present invention is to provide a daughter board, which exhibits not only data transmission functions but also data storage functions.

The present invent relates to a daughter board of a computer system to be connected to a front panel of a computer housing. The daughter board includes a main body, and on the main body a solid-state storage device for storing data and a control circuit in communication with the solid-state storage device for controlling data access to the solid-state storage device are disposed, for example, by surface mount technology.

The present invent further relates to the invention relates to a computer system, which includes a computer housing having a front panel; a daughter board connected to the front panel; a solid-state storage device mounted onto the daughter board; and a control circuit mounted onto the daughter board and being in communication with the solid-state storage device for controlling data access to the solid-state storage device.

### BRIEF DESCRIPTION OF THE DRAWINGS

The above contents of the present invention will become more readily apparent to those ordinarily skilled in the art after reviewing the following detailed description and accompanying drawings, in which:

FIG. 1A is a front view schematically showing a conventional front panel of a computer host;

FIG. 1B is a prospective view of the conventional front panel of FIG. 1A, showing the combination of the daughter board with the front panel; and

FIG. 2 is a functional block diagram illustrating a daughter board according to an embodiment of the present invention.

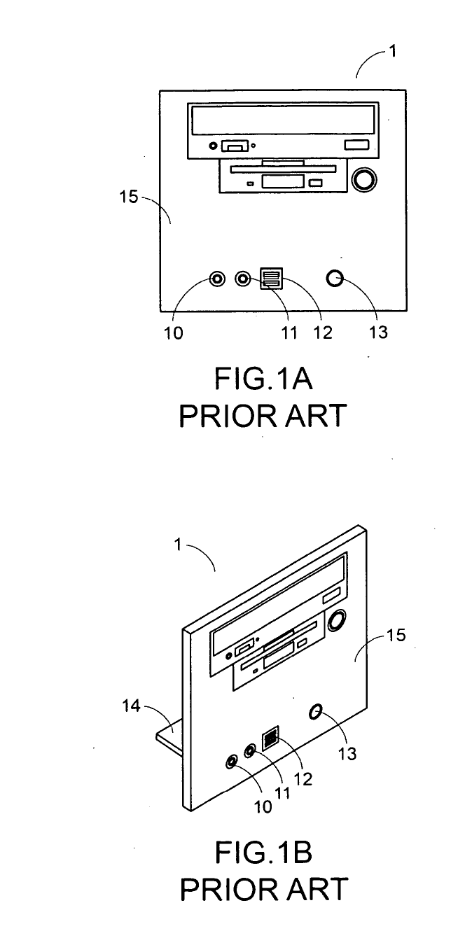

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

For achieving the object of exhibiting data storage functions, a control circuit and a solid-state storage device such as a solid-state drive (SSD) are additionally provided onto the daughter board.

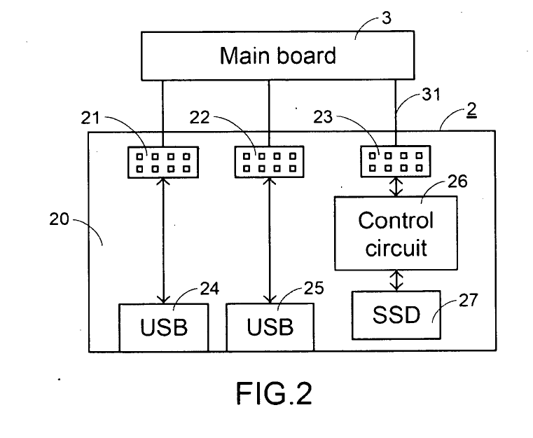

Please refer to FIG. 2, which illustrates a daughter board with a solid-state storage device according to an embodiment of the present invention. As illustrated, the daughter board 2 includes a main body 20 disposed thereon an SSD 27, a control circuit 26, circuitry associated with one or more USB ports, e.g. USB circuits 24 and 25, and a plurality of USB pins, e.g. pin sets 21, 22 and 23, for coupling the USB ports to internal circuitry of the computer via USB cables. Of course, circuitry associated with data transmission ports such as audio input/output ports, indicator lights and/or other suitable means (not shown) may also be disposed on the daughter board 2, and are not redundantly described and illustrated. In this embodiment, two of the USB pin sets 21 and 22 are coupled to the USB circuits 24 and 25 for allowing USB devices inserted into the USB ports to be electrically connected to a main board 3 of the computer, while the other one of the USB pin sets, e.g. the pin set 23, is not coupled to any USB circuit but coupled to the control circuit 26. The control circuit 26 is further in communication with the SSD 27 and receives commands from the main board 3 via the USB pin set 23 and a USB cable 31 to access data in the SSD 27.

In an alternative embodiment, the pin set 23 and the cable 31 can be of types other than USB. For example, an IEEE 1394 interface pin and an IEEE 1394 interface cable can be used for interfacing the control circuit 26 and SSD 27 with the internal circuitry of the computer.

Preferably, the SSD 27 and the control circuit 26 are provided onto the daughter board 2 by way of surface mount technology (SMT). The term “solid-state storage device” used herein basically but not necessarily refers to a flash-memory-type storage device which omits the mechanic structure of a conventional hard disk drive (HDD), and compared with a conventional HDD, has better shockproof effect, higher reliability, longer data storage duration, faster file search speed, and less power consumption, etc.

Since the SSD 27 is disposed onto the existing daughter board 2, no additional space inside the computer host is required for accommodating the data-storage-expanding device. The solid-state storage device, for example, may be used for maintaining important software programs such as operating systems, system recovery software, drivers, etc., in lieu of external floppy disks or compact disks which are subject to loss.

Furthermore, the use of the solid-state storage device for storing an operating system is advantageous in enhancing booting speed of the computer. The provision of the solid-state storage device on the daughter board has a further advantage that the solid-state storage device and the HDD may respectively store different operating systems, e.g. Windows XP and Linux, which can be selectively entered by the user in the booting procedure.

To sum up, according to the present invention, a daughter board with a solid-state storage device is provided to expand the use of the daughter board so as to additionally exhibit data storage functions.

While the invention has been described in terms of what is presently considered to be the most practical and preferred embodiments, it is to be understood that the invention needs not to be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A daughter board of a computer system to be mounted to a front panel of a computer housing, comprising:
a main body;
a solid-state storage device disposed on the main body for storing data; and
a control circuit disposed on the main body and being in communication with the solid-state storage device for controlling data access to the solid-state storage device.

2. The daughter board of a computer system according to claim 1, wherein the control circuit is coupled between a pin set and the solid-state storage device, and further in communication with a main board through the pin set and a cable.

3. The daughter board of a computer system according to claim 2, wherein the pin set and the cable are of a universal serial bus (USB) type or a IEEE 1394 type.

4. The daughter board of a computer system according to claim 1, wherein the solid-state storage device is a solid-state drive (SSD).

5. The daughter board of the computer system according to claim 1, wherein the solid-state storage device and the control circuit are mounted onto the daughter board by surface mount technology (SMT).

6. A computer system, comprising:
a computer housing having a front panel;
a daughter board connected to the front panel;
a solid-state storage device mounted onto the daughter board; and
a control circuit mounted onto the daughter board and being in communication with the solid-state storage device for controlling data access to the solid-state storage device.

7. The computer system according to claim 6, wherein the control circuit is coupled between a pin set and the solid-state storage device, and further in communication with a main board through the pin set and a cable.

8. The computer system according to claim 7, wherein the pin set and the cable are of a universal serial bus (USB) type or a IEEE 1394 type.

9. The computer system according to claim 6, wherein the solid-state storage device is a solid-state drive (SSD).

10. The computer system according to claim 6, wherein the solid-state storage device and the control circuit are mounted onto the daughter board by surface mount technology (SMT).
